(19) United States
(12) Patent Application Publication
(10) Pub. No.: US 2017/0076969 A1
(43) Pub. Date: Mar. 16, 2017

(54) METHOD OF MANUFACTURING SEMICONDUCTOR DEVICE

(71) Applicant: KABUSHIKI KAISHA TOSHIBA, Tokyo (JP)

(72) Inventors: Takashi SHIRONO, Oita Oita (JP); Mika FUJII, Oita Oita (JP); Kazuyuki HIGASHI, Yokohama Kanagawa (JP)

(21) Appl. No.: 15/233,920

(22) Filed: Aug. 10, 2016

(30) Foreign Application Priority Data
Sep. 11, 2015 (JP) 2015-180152

(51) Int. Cl. H01L 21/683; H01L 23/00; H01L 23/544; H01L 21/306; H01L 21/304; H01L 21/268

(52) U.S. Cl. CPC H01L 21/6835; H01L 21/304; H01L 21/268; H01L 23/544; H01L 21/30625; H01L 23/562; H01L 2221/68327; H01L 2221/6834; H01L 2223/54493

(57) ABSTRACT

According to one embodiment, a method of manufacturing a semiconductor device includes forming an overhanging portion in a perimeter region of a front surface side of a wafer provided with a semiconductor element on the front surface thereof by removing a portion of the wafer in perimeter region of the wafer from the front surface side of the wafer, bonding the front surface of the wafer to a supporting substrate, and thinning the wafer to less than 200 μm in thickness by grinding the wafer from a rear surface side thereof.

### CROSS-REFERENCE TO RELATED APPLICATION

This application is based upon and claims the benefit of priority from Japanese Patent Application No. 2015-180152, filed Sep. 11, 2015, the entire contents of which are incorporated herein by reference.

### FIELD

Embodiments described herein relate generally to a method of manufacturing a semiconductor device.

### BACKGROUND

In recent years, there is a method of manufacturing a thin semiconductor device by forming a semiconductor element on a front surface side of a wafer, bonding the front surface side of the wafer to a supporting substrate, and grinding and thinning the wafer from a rear surface side thereof.

In such a method of manufacturing a semiconductor device, since both front and rear surfaces adjacent to the perimeter of the wafer to be ground are beveled, the edge of the wafer can achieve a knife edge shape as the grinding proceeds, and the pointed portion of the perimeter or edge may be broken off from the wafer during the grinding. In this case, the flatness of the wafer is degraded due to the broken off fragments of the wafer edge becoming exposed to the grinding surface of the wafer, which may degrade the yield of the semiconductor device.

### DESCRIPTION OF THE DRAWINGS

FIG. 1 is a diagram illustrating an example of a wafer which is used in a method of manufacturing a semiconductor device according to an embodiment.

FIGS. 2A to 2D are cross-sectional views illustrating a process of manufacturing a semiconductor device according to a first embodiment.

FIG. 3 is a diagram illustrating test results obtained by evaluating the presence or absence of a crack in a perimeter region of the rear surface of a wafer according to the first embodiment.

FIG. 4 is a diagram illustrating test results obtained by evaluating the presence or absence of a crack in a perimeter region of the rear surface of a wafer according to the first embodiment.

FIGS. 5A to 5D are cross-sectional views illustrating a process of manufacturing a semiconductor device according to a second embodiment.

FIGS. 6A to 6D are cross-sectional views illustrating another process of manufacturing a semiconductor device according to the second embodiment.

FIGS. 7A to 7D are cross-sectional views illustrating a process of manufacturing a semiconductor device according to a third embodiment.

FIGS. 8A to 8D are cross-sectional views illustrating a process of manufacturing a semiconductor device according to a fourth embodiment.

### DETAILED DESCRIPTION

According to one embodiment, a method of manufacturing a semiconductor device includes forming an overhanging projection in a perimeter region of a front surface side of a wafer provided with a semiconductor element on the front surface thereof by removing a portion of the perimeter region of the wafer from the front surface side of the wafer, bonding the front surface of the wafer to a supporting substrate, and thinning the wafer to less than 200 μm in thickness by grinding the wafer from a rear surface side thereof.

Hereinafter, a method of manufacturing a semiconductor device according to an embodiment will be described with reference to the accompanying drawings. It is noted that the invention is not limited by the embodiment.

### First Embodiment

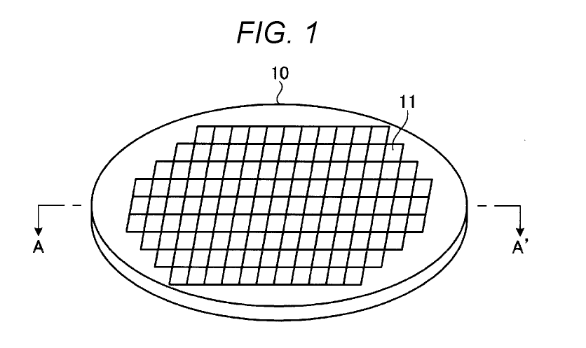

FIG. 1 is a diagram illustrating an example of a wafer which is used in a method of manufacturing a semiconductor device according to an embodiment. In the following embodiment, a description will be given of a process of preparing a wafer 10 provided with one or more semiconductor elements 11 and the like on the front surface side thereof, bonding together the wafer 10 and a supporting substrate (not shown in FIG. 1) to each other, and thinning the wafer 10 supported by the supporting substrate from the rear surface side thereof.

The wafer 10 used in the embodiment is, for example, a silicon wafer having a substantially disk shape, and both front and rear surfaces of the wafer at the perimeter of the wafer 10 are inclined inwardly of the thickness direction of the wafer, i.e., they are beveled.

A thin semiconductor device is manufactured by forming a semiconductor element and the like on a front surface side of a wafer, bonding the front surface of the wafer to a supporting substrate, and grinding and thinning the wafer from the rear surface side thereof.

In such a method of manufacturing a semiconductor device, since both the front and rear surfaces at the perimeter of the wafer to be ground are beveled, the circumferential edge of the wafer can achieve a knife edge shape as the grinding from the rear surface side toward the front surface side of the wafer proceeds, and thus the pointed knife edge formed during grinding of the wafer may be broken during the grinding. As a result, fragments of the wafer can become located at the grinding surface of the wafer to cause scratching of the surface of the wafer during grinding, and thus the flatness of the final ground surface of the wafer is degraded. For this reason, a relatively thin notch is generally formed i on the front surface side of the wafer along the wafer perimeter before the grinding to thereby prevent, in advance, the knife edge shape from forming.

However, when the thinning of the wafer proceeds by grinding the wafer from the rear surface side thereof, the perimeter of the wafer will have an eave or overhang shaped projection at the final stage of the grinding as the thickness of the wafer reaches a desired thickness, that is, the overhanging projection is formed at a position close to the front surface of the wafer in the thickness direction of the wafer. For this reason, in a case where the overhanging projection is broken off before the thickness of the wafer reaches a target thickness and all or part of the broken overhanging projection reaches the grinding surface of the wafer, the flatness of the ground surface of the thinned wafer may be impaired.

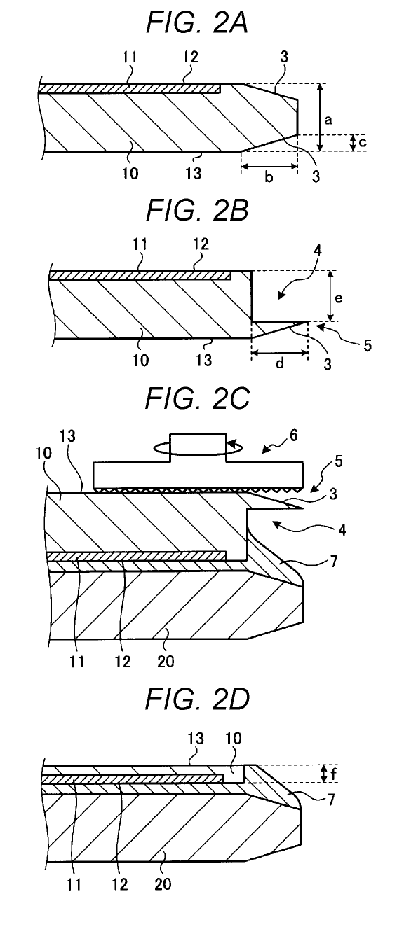

Consequently, in the method of manufacturing a semiconductor device according to the first embodiment, the overhanging projection is removed at an initial stage of the grinding, and at a position distant from the front surface of the wafer 10 in the thickness direction of the wafer 10 during grinding of the wafer 10 from the rear surface side thereof so that a grinding surface of the thinned wafer 10 which has high flatness is obtained. Hereinafter, such a method of manufacturing a semiconductor device will be described with reference to FIGS. 2A to 2D.

FIGS. 2A to 2D are cross-sectional views illustrating a process of manufacturing a semiconductor device according to an embodiment. The wafer 10 illustrated in FIGS. 2A to 2D is a portion of a cross-section taken along line A-A′ of the wafer 10 illustrated in FIG. 1. In the method of manufacturing a semiconductor device according to the first embodiment, at first, the wafer 10 and a supporting substrate 20 are prepared.

As illustrated in FIG. 2A, in this embodiment, a wafer 10 having a thickness a of, for example, 775 μm is used. Bevels 3 are formed in the perimeter region of the front surface 12 and in the perimeter of the rear surface 13 of the wafer 10. A width b of the bevel 3 10 extending from inwardly of the front and back surfaces 12, 13 from the wafer 10 circumferential edge or surface is, for example, 100 μm to 600 μm, and a height c of each bevel 3 in the thickness direction of the wafer 10 is, for example, 50 μm to 250 μm.

Next, as illustrated in FIG. 2B, an annular notch 4 is formed to extend inwardly of the wafer 10 edge around the entire perimeter region of the front surface 12 of the wafer 10 so as to have a depth e extending inwardly of the front surface 12 of the wafer 10 of more than one-fourth of the thickness a of the wafer 10, for example, a depth of 200 μm to 500 μm from the front surface 12 of the wafer 10, by etching. In this embodiment, the width d of the notch 4 on the front surface 12 of the wafer 10 extending inwardly of the edge of the wafer 10 is substantially the same as the width b of the bevel 3 formed therein and is, for example, 600 μm. In other words, the notch 4 is formed by removing the bevel 3 around the circumference of the front surface 12 of the wafer 10 by etching.

Thereby, an overhanging projection 5 is formed at the perimeter region of the rear surface 13 of the wafer 10. However, the overhanging projection 5 is formed at a position distant from the front surface 12 of the wafer 10 in the thickness direction of the wafer 10 by the depth of the notch 4. Therefore, it is possible to remove the overhanging projection 5 at an initial stage of grinding during grinding and thinning of the wafer 10 from the rear surface side 13 thereof.

For this reason, in this embodiment, a notch 4 reaching at least 200 μm or more in depth e from the front surface 12 of the wafer 10 is formed. Thereby, it is possible to flatten the rear surface 13 of the wafer 10 while the wafer 10 is thinned to a desired thickness.

Subsequently, as illustrated in FIG. 2C, the front surface 12 of the wafer 10 which is inverted from the position thereof in FIG. 2b and is bonded to the supporting substrate 20 by an adhesive 7. As the adhesive 7, an organic adhesive such as a urethane-based resin or an epoxy resin is used.

In addition, the adhesive 7 mentioned above is applied onto the front surface of the supporting substrate 20 by a spin coating method or the like. In addition, the supporting substrate 20 is formed of, for example, glass, silicon, or the like, and is a disk-shaped substrate having substantially the same diameter and thickness as those of the wafer 10. It is noted that the diameter, thickness, and the like of the supporting substrate 20 are not limited thereto.

Here, as illustrated in FIG. 2C, regarding the presence of adhesive 7 in the notch portion 4 after bonding, the adhesive 7 pressed along the side wall of the notch 4 during bonding of the wafer 10 to the substrate 20 stops before reaching the bottom of the notch 4 due to a large depth e of the notch 4.

For this reason, when the rear surface 13 of the wafer 10 is ground, the overhanging projection 5 is not firmly fixed to the adhesive 7, and thus the overhanging projection 5 can be easily removed.

Referring back to FIG. 2C, thereafter, the wafer 10 is ground from the rear surface 13 thereof by a grinder 6 so as thin the wafer 10 to less than 200 μm in thickness, specifically, for example, to 33 μm in thickness.

Here, the location of the overhanging projection 5 formed along the perimeter of the rear surface 13 of the wafer 10 removed by grinding is located spaced from the front surface 12 of the wafer 10 in the thickness direction of the wafer 10. For this reason, even when the overhanging projection 5 is broken and becomes involved in the grinding surface of the wafer 10, the grinding surface of the wafer 10 is flattened while the wafer 10 is thinned to a desired thickness.

That is, in this embodiment, the overhanging projection 5 is removed at a position spaced from the front surface 12 of the wafer, so that influence on uniform grinding of the wafer flatness due to the mixing of wafer pieces of the overhanging projection 5 with the grinding surface is ameliorated as the grinding of the rear surface 13 of the wafer 10 comes close to a final stage, and thus the grinding surface of the wafer 10 is gradually flattened.

As illustrated in FIG. 2D, when the wafer 10 is thinned to a desired thickness f, in this example, 33 μm in thickness by grinding, the rear surface 13 of the wafer 10 which is flattened with a high level of accuracy is obtained.

Thereafter, the rear surface 13 of the wafer 10 is smoothly finished by chemical mechanical polishing (CMP) thereof. In addition, a post-process such as a process of removing the wafer 10 from the supporting substrate 20 and dicing the wafer 10 is performed.

As described above, the method of manufacturing a semiconductor device according to the first embodiment includes three processes comprising a formation process, a bonding process, and a grinding process. In the formation process, an area extending inwardly of the edge of the wafer 10 provided with the semiconductor element 11 on the front surface 12 thereof is removed to at least 200 μm or more in depth e from the front surface 12 of the wafer 10, thereby forming the notch 4 extending inwardly of the circumferential edge of the wafer 10 on the front surface side of the wafer 10.

In the bonding process, the front surface 12 of the wafer 10 is bonded to the supporting substrate 20 using an intervening adhesive 7. In the thinning process, the rear surface 13 of the wafer 10 is ground to thin the wafer 10 to less than 200 μm in thickness f.

Thereby, in the method of manufacturing a semiconductor device according to the first embodiment, in a case where the wafer 10 bonded to the supporting substrate 20 is ground from the rear surface 13 thereof, it is possible to obtain the rear surface 13 of the wafer 10 which is flattened with a high level of accuracy and to improve the yield of the semiconductor device.

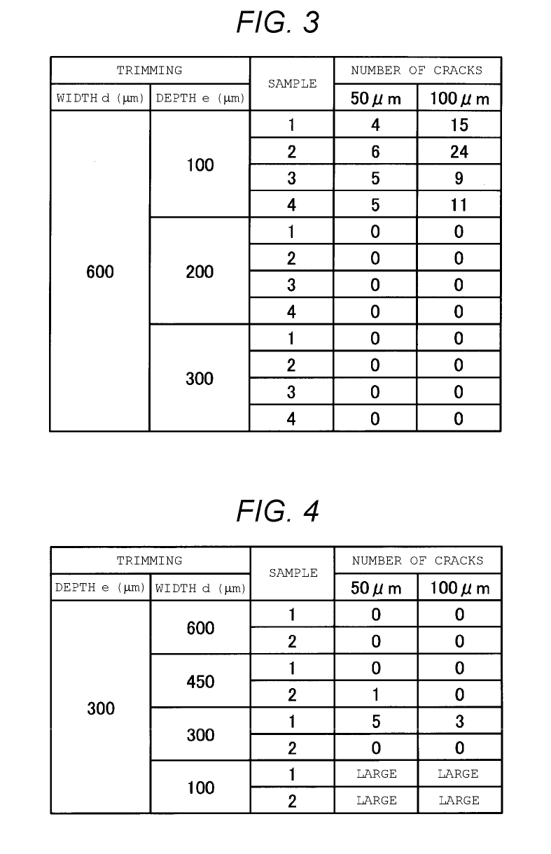

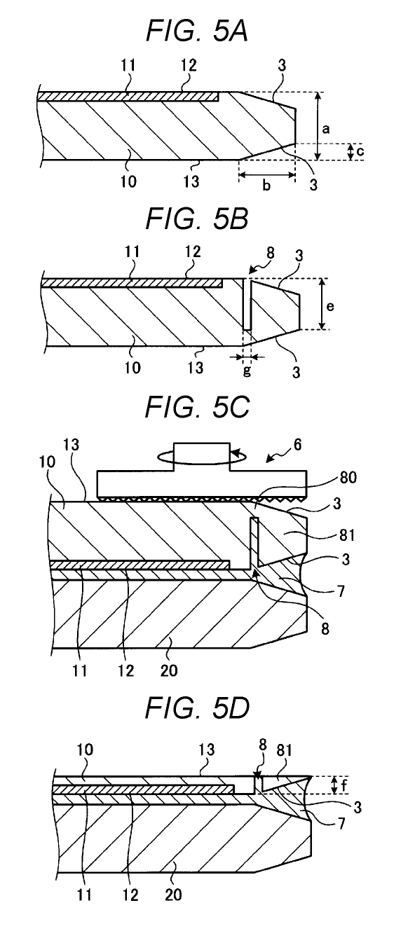

Here, a description will be given of test results obtained by evaluating the presence or absence of a crack in the perimeter region of the rear surface 13 of the wafer 10 after grinding for different depths e of the notch 4. FIGS. 3 and 4 are diagrams illustrating test results obtained by evaluating the presence or absence of a crack in the perimeter portion of the rear surface 13 of the wafer 10 manufactured according to the first embodiment.

Specifically, FIG. 3 illustrates test results obtained by evaluating the number of cracks in the perimeter region of the rear surface 13 of a plurality of wafers 10 after the wafer 10 is subjected to notching in the perimeter region with a fixed width d of the notch 4 being set to 600 μm and the depth e of the notch being varied. Each sample comprises a wafer having a notch width of 600 μm and a notch depth of one of 100 μm, 200 μm or 300 μm, which is bonded to a supporting substrate 20 and then thinned to a predetermined thickness f by grinding the rear surface 13 thereof. In the test, the number of cracks present in the perimeter region of each sample having a length of 50 μm and a length of 100 μm was evaluated.

FIG. 4 illustrates test results obtained by evaluating the number of cracks in the perimeter region of the rear surface 13 of the wafer 10 after the wafer 10, which is subjected to notching with a fixed depth e being set to 300 μm and a width d being one of 100 μm, 200 μm or 300 μm, is bonded to the supporting substrate 20 and is thinned to a predetermined thickness f from the rear surface 13 thereof. A thickness a of the wafers 10 used in the test was 775 μm, and the thickness f of the thinned wafers 10 was 33 μm. In addition, a width b of a bevel 3 formed therein was 350 μm, and a height c of the bevel 3 was 200 μm.

As illustrated in FIG. 3, in samples 1 to 4 in which a depth e of the notch 4 is 100 μm, the number of cracks having a length of 50 μm was less than ten, but the number of cracks having a length of 100 μm exceeded ten or more in three of the four samples, and thus a large number of cracks was present in the perimeter region of the rear surface 13 of the thinned wafer 10.

On the other hand, in samples 1 to 4 in which a depth e of the notch 4 is 200 μm and samples 1 to 4 in which a depth e of the notch 4 is 300 μm, no cracks having a length of 50 μm or a length of 100 μm were present in the perimeter region of the rear surface 13 of the thinned wafer 10.

From this, it is understood that the generation of a crack in the perimeter region of the rear surface 13 of the thinned wafer 10 can be suppressed when the depth e of the notch 4 extends inwardly of the front surface 12 of the wafer 10 to a depth at least equal to or greater than 200 μm.

As described above, when the depth e of the notch 4 is large, the adhesive 7 in the notch 4 after bonding stops along a side wall of the notch 4 without reaching the bottom of the notch 4. Thereby, since the overhanging projection 5 is not firmly fixed by the adhesive 7 at the time of grinding the wafer 10 from the rear surface 13 thereof, it is possible to easily remove the overhanging projection 5, and thus the generation of a crack in the perimeter region of the rear surface 13 of the ground wafer 10 is suppressed.

In addition, as illustrated in FIG. 4, it has been found that the number of cracks in the perimeter region of the rear surface 13 of the thinned wafer 10 is reduced as the width d of the notch 4 extending inwardly of the edge of the wafer 10 increases from 100 μm to 600 μm. In other words, if the width d of the notch 4 is set to 600 μm, which is the same as the width b of the bevel 3 at the perimeter region of the wafer, the generation of a crack at the perimeter region of the rear surface 13 of the thinned wafer 10 can be suppressed.

### Second Embodiment

Next, a method of manufacturing a semiconductor device according to a second embodiment will be described. In this embodiment, the first surface 12 of the wafer is cut into at a position inwardly of the edge of a wafer so as to reach a desired depth of cut from a front surface 12 side of the wafer 10 and the cut continues around the circumference of the wafer, in contrast to forming a notch inwardly of the front surface side 12 of the wafer 10.

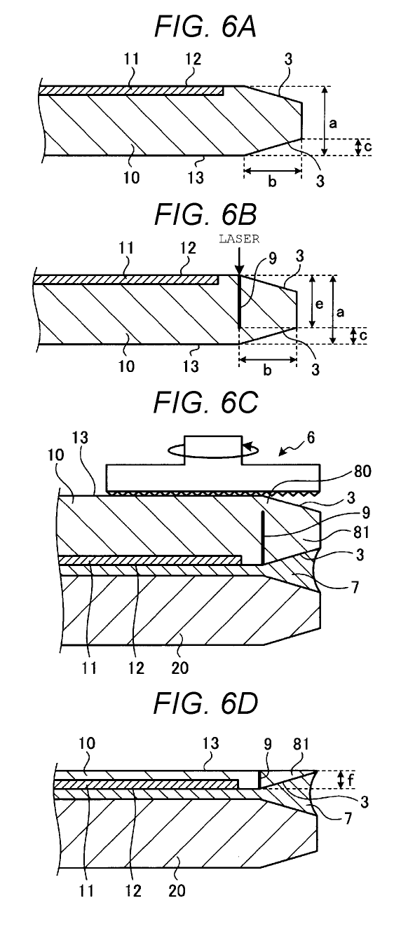

FIGS. 5A to 5D are cross-sectional views illustrating a process of manufacturing a semiconductor device according to the second embodiment. Among components illustrated in FIGS. 5A to 5D, components that are the same as those illustrated in FIGS. 2A to 2D will be denoted by the same reference numerals and signs, and a repeated description thereof will be omitted here. In the method of manufacturing a semiconductor device according to the second embodiment, at first, a wafer 10 (see FIG. 5A) and a supporting substrate 20 are prepared.

Next, as illustrated in FIG. 5B, a groove 8 is formed into the upper surface of the wafer 10 so as to have a depth e of more than one-fourth of the thickness a of the wafer 10, for example, a depth of 200 μm to 500 μm from a front surface 12 of the wafer 10, at a location inwardly of the edge of the wafer 10 around the wafer 10 circumference, using a dicing blade.

The groove 8 has a groove width g extending from a location on the upper surface 12 bevel 3 of the wafer 10 located inwardly of the outer edge of the wafer to a position extending inwardly of the depth of the wafer 10 in a horizontal direction to a distance of, for example, less than 200 μm to 600 μm. When the groove has a maximum spacing from the outer edge of the wafer 10 of, for example, 1000 μm, the groove 8 is formed across the bevel 3 region of the front surface 12 of the wafer 10 on a semiconductor element 11 side thereof. In this case, a portion of the first surface 12 of the wafer extends from the groove 8 to the semiconductor element 11 region of the wafer 10.

Subsequently, as illustrated in FIG. 5C, the front surface 12 of the wafer 10, which is inverted from the position thereof shown in FIG. 5B, is bonded to a supporting substrate 20 using an adhesive 7. The adhesive 7 mentioned above is applied onto the front surface 12 of the wafer 10 by a spin coating method or the like.

Thereafter, the rear surface 13 of the wafer 10 is ground by a grinder 6 so as to thin the wafer 10 to less than 200 μm in thickness, specifically, a thickness of, for example, 33 μm.

A portion 80 in the perimeter region of the rear surface 13 of the wafer 10 which is not separated by the groove portion 8 is removed by grinding at a position spaced from the front surface 12 of the wafer in the thickness direction of the wafer 10. For this reason, even when the portion 80 is broken and it becomes involved in the grinding surface of the wafer 10, the grinding surface of the wafer 10 is later flattened as the wafer 10 is thinned to a desired thickness.

That is, in this embodiment, the portion 80 forming an overhanging projection extending around the circumference of the substrate 10 is spaced from the front surface 12 of the wafer, and is removed at the beginning of the grinding operation to thin the wafer 10, so that influence on the back surface 13 flatness due to the mixing of wafer pieces of the portion 80 with the grinding surface is solved as the grinding of the rear surface 13 of the wafer 10 comes close to a final stage, and thus the ground surface of the wafer 10 is gradually flattened.

A portion 81 in the perimeter of the wafer 10 which is separated or isolated from the remainder of the wafer 10 by the groove 8 is firmly fixed to the wafer 10 by the adhesive 7, and thus there is no concern that the portion 81 will reach the grinding surface of the wafer 10 during grinding.

As illustrated in FIG. 5D, when the wafer 10 is thinned to a desired thickness f, in this example, to 33 μm in thickness by grinding, the rear surface 13 of the wafer 10 which is flattened to a high level of accuracy is obtained.

Thereafter, the rear surface 13 of the wafer 10 is smoothly finished by CMP. In addition, a post-process such as a process of removing the wafer 10 from the supporting substrate 20 and dicing the wafer 10 is performed.

As described above, the method of manufacturing a semiconductor device according to the second embodiment includes three processes comprising a process of forming a circumferential groove in the bevel 3 region at a location inwardly of the outer edge of the wafer 10, a bonding process, and a thinning process. In the grooving process, the groove 8 is formed in the perimeter region of the wafer 10 provided with the semiconductor element 11 on the front surface 12 thereof to at least 200 μm or more in depth e from the front surface 12 of the wafer 10 at a location inwardly of the outer edge of the wafer 10 using a dicing blade.

In the bonding process, the front surface 12 of the wafer 10 is bonded to the supporting substrate 20 with the adhesive 7. In the thinning process, the rear surface 13 of the wafer 10 is ground to thin the wafer 10 to less than 200 μm in thickness f.

Thereby, in the method of manufacturing a semiconductor device according to the second embodiment, in a case where the rear surface 13 of a wafer 10 bonded to the supporting substrate 20 is ground to thin the wafer 10, it is possible to obtain a rear surface 13 of the wafer 10 which is flattened with a high level of accuracy and to improve the yield of the semiconductor device.

In the method of manufacturing a semiconductor device according to the second embodiment described above, grooving is performed in the perimeter region of the wafer 10 using a dicing blade. Alternatively, virtual grooving may be performed using a laser. In that case a portion of the wafer 10 having a lower mechanical strength than that of the portion of the wafer 10 which is not processed by a laser may be created by performing irradiation with a laser.

Specifically, a portion of the wafer having a low mechanical strength is formed by the laser irradiation at a location inwardly of the edge of the wafer 10 so as to have a depth e of more than one-fourth of a thickness a of the wafer 10, for example, a depth of 200 μm to 500 μm from the front surface 12 of the wafer 10 at a location inwardly of the edge of the wafer 10, using a laser.

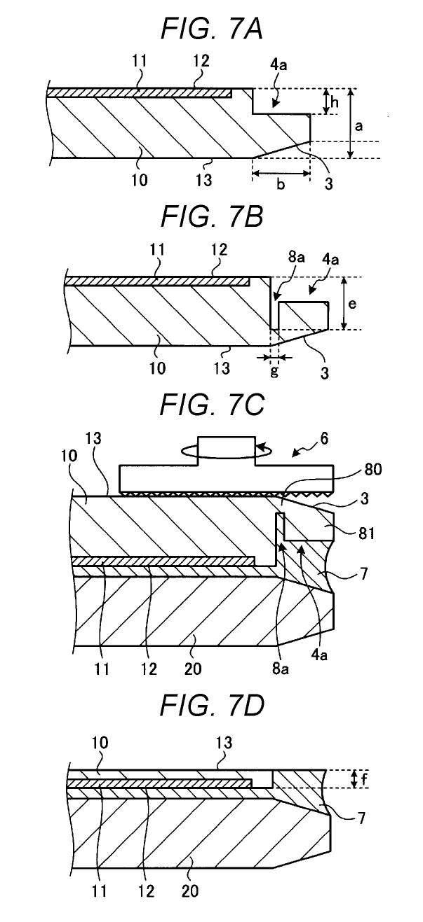

In an example illustrated in FIGS. 6A to 6D, a portion 9 having a low mechanical strength is formed to have a depth e of at least equal to or greater than 200 μm from the front surface 12 of the wafer 10 along the outer periphery of the wafer 10, using a laser. FIGS. 6A to 6D are cross-sectional views illustrating another process of manufacturing a semiconductor device according to the second embodiment. The processes illustrated in FIGS. 6A to 6D are the same as the processes illustrated in FIGS. 5A to 5D except that the portion 9 having a low mechanical strength is formed in the perimeter region on a front surface side of the wafer 10 about the circumference of the wafer 10 using a laser.

As illustrated in FIG. 6B, a location on the front surface 12 of the wafer 10 at the inward end of, or inwardly of the front surface 12 from, the inward end of the bevel 3 is irradiated with a laser. Thereby, a portion 9 in the wafer 10 having a low mechanical strength is formed along the perimeter region of the wafer 10 inwardly of the edge thereof so as to have a depth e of at least equal to or greater than 200 μm from the front surface 12 of the wafer 10 and thereby form an overhanging projection at the edge of the wafer 10.

In addition, the wafer 10 is thinned to a desired thickness f by grinding through the processes illustrated in FIGS. 6C and 6D to thereby obtain a rear surface 13 of the wafer 10 which is flattened with a high level of accuracy.

Even with such a configuration, in a case where the wafer 10 bonded to the supporting substrate 20 is ground to be thinned from the rear surface 13 side, it is possible to obtain the rear surface 13 of the wafer 10 which is flattened with a high level of accuracy and to improve the yield of the semiconductor device.

In such a configuration, a virtual grooving created by weakening an area of the substrate is performed inwardly of the edge of the wafer 10 using a laser, and thus it is possible to finely finish a dicing surface of the wafer 10.

### Third Embodiment

Next, a method of manufacturing a semiconductor device according to a third embodiment will be described. In this embodiment, after a notch is formed in a periphery on a front surface side of a wafer by removing a portion of the wafer extending inwardly of the edge thereof, grooving is performed on the base of the notch to a desired depth from the front surface side of the wafer around the wafer.

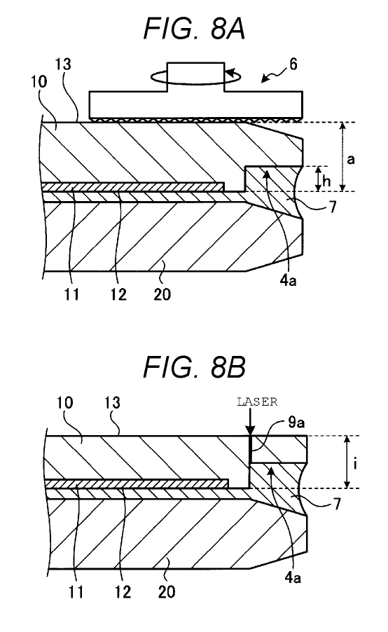

FIGS. 7A to 7D are cross-sectional views illustrating a process of manufacturing a semiconductor device according to the third embodiment. Among components illustrated in FIGS. 7A to 7D, components that are the same as those illustrated in FIGS. 5A to 5D will be denoted by the same reference numerals and signs, and a repeated description thereof will be omitted here. In the method of manufacturing a semiconductor device according to the third embodiment, at first, a wafer 10 (see FIG. 5A) and a supporting substrate 20 are prepared.

Next, as illustrated in FIG. 7A, a shallow annular notch 4a is formed in the perimeter region of the wafer 10 inwardly from the wafer edge to a depth h of less than one-fifth of a thickness a of the wafer 10, for example, a depth of 50 μm to 150 μm from the front surface 12 of the wafer 10 around the circumference of the wafer 10, by etching. In this embodiment, the width of the notch 4a is substantially the same width as a width b of the bevel 3 extending inwardly of the wafer 10 from the edge of the wafer 10. In other words, the notch 4a is formed by removing the bevel 3 on the first surface 12 of the wafer 10 by etching.

Subsequently, as illustrated in FIG. 7B, a groove 8a is formed in the perimeter region of the wafer 10 in the notch 4a formed therein at a location inwardly of the wafer edge to a depth e of more than one-fourth of a thickness a of the wafer, for example, a depth of 200 μm to 500 μm from a front surface 12 of the wafer 10 around the circumference of the wafer 10, using a dicing blade. The groove 8a is formed outwardly from the inner peripheral surface side of the notch portion 4a to form the overhanging projection around the circumference of the wafer 10.

Subsequently, as illustrated in FIG. 7C, the front surface 12 of the wafer 10 which is inverted is bonded to the supporting substrate 20 with an adhesive 7. The adhesive 7 mentioned above is applied onto the front surface 12 of the wafer 10 by a spin coating method or the like. Thereafter, the rear surface 13 of the wafer 10 is ground using a grinder 6 so as to be thin the wafer 10 to less than 200 μm in thickness, specifically, a thickness of, for example, 33 μm.

As illustrated in FIG. 7D, the wafer 10 is thinned to a desired thickness f, in this example, 33 μm in thickness by grinding, and thus the rear surface 13 of the wafer 10 which is flattened with a high level of accuracy is obtained.

Thereafter, the rear surface 13 of the wafer 10 is smoothly finished by CMP. In addition, a post-process such as a process of removing the wafer 10 from the supporting substrate 20 and dicing the wafer 10 is performed.

As described above, the method of manufacturing a semiconductor device according to the third embodiment includes four processes comprising a formation process, a process of forming a groove, a bonding process, and a thinning process. In the formation process, a shallow annular notch 4a is formed in the front surface side of the wafer 10 by removing a portion of the wafer 10 extending inwardly of the edge of the front side of the wafer 10 on the front surface 12 thereof to one-fifth of a thickness a of the wafer 10 or less in depth h from the front surface 12 of the wafer 10.

In the process of grooving, a groove portion 8a is formed at a location inwardly of the edge of the wafer 10 to a depth e of at least equal to or greater than 200 μm from the front surface 12 of the wafer 10 in the notched area of the wafer 10 using a dicing blade.

In the bonding process, the front surface 12 of the wafer 10 is bonded to the supporting substrate 20 with the adhesive 7. In the thinning process, the rear surface 13 of the wafer 10 is ground to thin the wafer 10 to less than 200 μm in thickness f.

Thereby, in the method of manufacturing a semiconductor device according to the third embodiment, in a case where the wafer 10 bonded to the supporting substrate 20 is ground from the rear surface 13 to thin the wafer 10, it is possible to obtain the rear surface 13 of the wafer 10 which is flattened with a high level of accuracy and to improve the yield of the semiconductor device.

In such a configuration, after the shallow annular notch 4a continuing along the circumference of the wafer 10 is formed by removing the portion of the front surface 12 at the perimeter region of the wafer 10, the groove 8a is formed in the perimeter region of the wafer 10 to have a desired depth from the bottom of the notch 4a, using a dicing blade.

Therefore, as illustrated in FIG. 7D, wafer pieces in a portion having the notch portion 4a formed therein in the perimeter region of the wafer 10 are removed when grinding is terminated, and thus it is possible to easily remove the wafer 10, subjected to the grinding of the rear surface thereof, from the supporting substrate 20.

In such a configuration, grooving is performed on the perimeter region of the wafer 10 using a dicing blade. Alternatively, virtual grooving, i.e. forming a weakened area, may be performed using a laser in place of grooving the wafer 10 with a dicing blade. Specifically, a portion having a low mechanical strength is formed in the perimeter region of the wafer 10 having the notch portion 4a formed therein to a depth e of at least equal to or greater than 200 μm from the front surface 12 of the wafer 10 around the circumference of the wafer 10, using a laser.

Even with such a configuration, in a case where rear surface 13 of the wafer 10 bonded to the supporting substrate 20 is ground to thin the wafer, it is possible to obtain the rear surface 13 of the wafer 10 which is flattened with a high level of accuracy and to improve the yield of the semiconductor device.

### Fourth Embodiment

Next, a method of manufacturing a semiconductor device according to a fourth embodiment will be described. In this embodiment, after the rear surface of the notched wafer is ground to form a wafer 10 having a desired thickness, a portion having a low mechanical strength is formed in a perimeter region of the wafer to a desired depth from the rear surface of the wafer, using a laser.

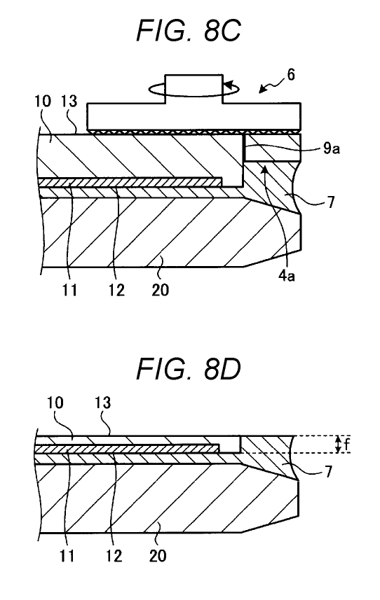

FIGS. 8A to 8D are cross-sectional views illustrating a process of manufacturing a semiconductor device according to a fourth embodiment. Among components illustrated in FIGS. 8A to 8D, components that are the same as those illustrated in FIGS. 5A to 5D and FIGS. 7A to 7D will be denoted by the same reference numerals and signs, and a repeat description thereof will be omitted here. In the method of manufacturing a semiconductor device according to the fourth embodiment, at first, a wafer 10 (see FIG. 5A) and a supporting substrate 20 are prepared.

Next, a shallow annular notch 4a is formed in the perimeter region of the wafer 10 to a depth h of less than one-fifth of a thickness a of the wafer 10, for example, a depth of 50 μm to 150 μm from a front surface 12 of the wafer 10, around the circumference of the wafer 10, by etching (see FIG. 7A).

Subsequently, as illustrate in FIG. 8A, the front surface 12 of the wafer 10 which is inverted is bonded to a supporting substrate 20 through an adhesive 7. The adhesive 7 mentioned above is applied onto the front surface 12 of the wafer 10 by a spin coating method or the like. Thereafter the rear surface 13 of the wafer 10 is ground by a grinder 6 so as to be thin the wafer 10 to half the original thickness a of the wafer 10 or more in thickness i, for example, 400 μm in thickness from the front surface 12 of the wafer 10.

As illustrated in FIG. 8B, a portion 9a having a low mechanical strength is formed in the perimeter region of the wafer 10 from the rear surface 13 of the wafer 10 to the front surface 12 having the notch 4a formed thereon using a laser, thereby forming an overhanging projection weakly attached to the remainder of the wafer 10 through the weakened portion 9a. Specifically, a portion 9a having a lower mechanical strength than that of a portion of the wafer 10 which is not processed by a laser is formed by performing irradiation with a laser directly on the inner peripheral surface of the notch portion 4a in the perimeter region of the wafer 10.

Next, as illustrated in FIG. 8C, the rear surface 13 of the wafer 10 is again ground using the grinder 6 so as to thin the wafer 10 to less than 200 μm in thickness, specifically, for example, 33 μm in thickness.

As illustrated in FIG. 8D, the wafer 10 is thinned to a desired thickness f, in this example, 33 μm in thickness by grinding, and thus the rear surface 13 of the wafer 10 which is flattened with a high level of accuracy is obtained.

Thereafter, the rear surface 13 of the wafer 10 is smoothly finished by CMP. In addition, a post-process such as a process of removing the wafer 10 from the supporting substrate 20 and dicing the wafer 10 is performed.

As described above, the method of manufacturing a semiconductor device according to the fourth embodiment includes five processes comprising a formation process, a bonding process, a first thinning process, a process of performing dicing, and a second thinning process. In the formation process, a shallow notch 4a is formed in the perimeter region on the front surface side of the wafer 10 to one-fifth of a thickness a of the wafer 10 or less in depth h from the front surface 12 of the wafer 10.

In the bonding process, the front surface 12 of the wafer 10 is bonded to the supporting substrate 20 with the adhesive 7. In the first thinning process, the rear surface 13 of the wafer 10 is ground so as to thin the wafer 10 to half the original thickness a of the wafer 10 or more in thickness i from the front surface 12 of the wafer 10.

In the process of performing virtual grooving, a portion 9a having a low mechanical strength is formed in the perimeter region of the wafer 10 from the rear surface 13 of the wafer 10 to the portion of the front surface 12 having the notch 4a formed thereon, using a laser. In the second thinning process, the rear surface of the wafer 10 is further ground so to thin the wafer 10 to less than 200 μm in thickness f.

Thereby, in the method of manufacturing a semiconductor device according to the fourth embodiment, in a case where the wafer 10 bonded to the supporting substrate 20 is ground on the rear surface 13 side thereof to thin the wafer 10, it is possible to obtain the rear surface 13 of the wafer 10 which is flattened with a high level of accuracy and to improve the yield of the semiconductor device.

In such a configuration, after the shallow annular notch portion 4a continuing along the perimeter region of the wafer 10 is formed, the portion 9a having a low mechanical strength is formed along in the perimeter region of the wafer 10 from the rear surface 13 of the wafer 10 to the base of the notch 4a, using a laser.

Therefore, as illustrated in FIG. 8D, wafer pieces in a portion having the notch 4a formed therein in the perimeter region of the wafer 10 are removed when grinding is terminated, and thus it is possible to easily remove the wafer 10, subjected to the grinding of the rear surface thereof, from the supporting substrate 20.

Meanwhile, in such a configuration, after the rear surface 13 of the wafer 10 is ground to a desired thickness i, virtual grooving is performed on the perimeter of the wafer 10 using a laser. For this reason, it is possible to reduce an irradiation time of a laser with respect to the wafer 10 and to suppress the influence of heat on the wafer 10 due to a laser.

In such a configuration, virtual grooving is performed on the perimeter region of the wafer 10 using a laser, and thus it is possible to finely finish a dicing surface of the wafer 10.

In the methods of manufacturing a semiconductor device according to the first to fourth embodiments, the front surface 12 of the wafer 10 is bonded to the supporting substrate 20 with the adhesive 7. It is noted that methods are not limited thereto. According to another method, the front surface 12 of the wafer 10 may be directly bonded to the supporting substrate 20 without using the adhesive 7.

Even with such a method, in a case where the wafer 10 bonded to the supporting substrate 20 is grounded from the rear surface 13 to thin the wafer 10, it is possible to obtain the rear surface 13 of the wafer 10 which is flattened with a high level of accuracy and to improve the yield of the semiconductor device.

While certain embodiments have been described, these embodiments have been presented by way of example only, and are not intended to limit the scope of the inventions. Indeed, the novel embodiments described herein may be embodied in a variety of other forms; furthermore, various omissions, substitutions and changes in the form of the embodiments described herein may be made without departing from the spirit of the inventions. The accompanying claims and their equivalents are intended to cover such forms or modifications as would fall within the scope and spirit of the inventions.

What is claimed is:

1. A method of manufacturing a semiconductor device, the method comprising:
forming an overhanging projection in a perimeter region of a front surface side of a wafer provided with a semiconductor element on the front surface thereof by removing a portion of the perimeter region of the wafer from the front surface of the wafer;
bonding the front surface of the wafer to a supporting substrate; and
thinning the wafer to less than 200 μm in thickness by grinding the wafer from a rear surface side thereof.

2. The method according to claim 1, further comprising forming the overhanging projection at a location spaced from the front surface of the wafer by forming a notch at the perimeter region of the wafer which extends inwardly of the front surface of the wafer by at least 200 μm.

3. The method of claim 2, further comprising bonding the wafer to the supporting structure with an adhesive, and extending the adhesive only partially inwardly of the notch during the bonding of the wafer to the supporting substrate.

4. The method according to claim 1, further comprising forming the overhanging projection at a location spaced from the front surface of the wafer by forming a notch at the perimeter region of the wafer extending inwardly of the front surface side of the wafer to a depth less than one-fifth of a thickness of the wafer; and
extending a groove inwardly of the substrate from the base of the notch.

5. The method according to claim 4, further comprising bonding the wafer to the supporting structure with an adhesive, and extending the adhesive at least partially inwardly of the groove.

6. The method according to claim 1, further comprising forming the overhanging projection at a location spaced from the front surface of the wafer by forming a notch at the perimeter region of the wafer extending inwardly of the front surface side of the wafer to a depth less than one-fifth of a thickness of the wafer; and
forming a weakened portion of the substrate to extend inwardly of the substrate from the base of the notch.

7. The method according to claim 1, further comprising forming the overhanging projection at a location spaced from the front surface of the wafer by forming a groove in the perimeter region of the wafer, at a position spaced from the wafer edge, to extend inwardly of the front surface side of the wafer.

8. The method according to claim 7, further comprising bonding the wafer to the supporting structure with an adhesive, and extending the adhesive at least partially inwardly of the groove.

9. The method according to claim 1, further comprising forming the overhanging projection at a location spaced from the front surface of the wafer by forming a weakened portion of the wafer in the perimeter region of the wafer, at a position spaced from the wafer edge, to extend inwardly of the front surface side of the wafer.

10. The method according to claim 9, wherein the weakened portion comprises a portion of the wafer having lower mechanical strength than the portion of the wafer thereadjacent, formed by a laser.

11. An assembly for thinning a wafer, comprising: a wafer having a device side surface, a back side surface on the opposite side of the wafer as the device side, and a perimeter region extending on the device side surface inwardly of a circumferential edge of the wafer; and
a supporting substrate bonded to the device side surface of the wafer; wherein
the wafer comprises an overhanging projection extending inwardly of the circumferential edge thereof at the front surface side thereof and spaced from the second surface side thereof.

12. The assembly of claim 11, further comprising an adhesive intervening between the device side surface of the wafer and the supporting surface.

13. The assembly of claim 12, further comprising a notch extending inwardly of the edge and the device surface side of the wafer, and the depth of the notch from the device surface side of the wafer is at least 200 μm.

14. The assembly of claim 12, further comprising a groove extending inwardly of the device surface side of the wafer to a depth of more than one-fourth of the thickness a of the wafer, at a location spaced from the circumferential edge of the wafer.

15. The assembly of claim 12, further comprising a weakened portion of the substrate extending inwardly of the device surface side of the wafer to a depth of at least 200 μm, at a location spaced from the circumferential edge of the wafer.

16. A method of improving the flatness of a backside of a ground wafer, comprising:
forming an isolated portion of the wafer extending from the remainder of the wafer in a perimeter region of a rear surface side of a wafer provided with a semiconductor element on the front surface thereof by modifying a portion of the perimeter region of the wafer;
bonding the front surface of the wafer to a supporting substrate; and
thinning the wafer to less than 200 μm in thickness by grinding the wafer from a rear surface side thereof.

17. The method of claim 16, further comprising forming the isolated region by forming a groove in the perimeter region of the wafer, at a position spaced from the wafer edge, to extend inwardly of the front surface side of the wafer.

18. The method of claim 17, wherein the groove extends inwardly of the front surface side of the wafer to a depth of at least one-fifth the thickness of the wafer.

19. The method of claim 16, further comprising forming the isolated region by forming a weakened portion of the wafer in the perimeter region of the wafer, at a position spaced from the wafer edge, to extend inwardly of the front surface side of the wafer.

20. The method of claim 19, wherein the weakened portion extends inwardly of the front surface side of the wafer to a depth of at least one-fifth the thickness of the wafer.
